(19) United States
(12) Patent Application Publication
(10) Pub. No.: US 2026/0033248 A1
(43) Pub. Date: Jan. 29, 2026

(54) SUPERCONDUCTOR-BASED QUANTUM COMPUTERS AND METHODS OF OPERATING THE SAME

(71) Applicant: Samsung Electronics Co., Ltd., Suwon-si (KR)

(72) Inventors: Daeseok HAN, Suwon-si (KR); Jaehyeong LEE, Suwon-si (KR); Jaeho SHIN, Suwon-si (KR); Insu JEON, Suwon-si (KR)

(73) Assignee: Samsung Electronics Co., Ltd., Suwon-si (KR)

(21) Appl. No.: 18/659,695

(22) Filed: May 9, 2024

(30) Foreign Application Priority Data
Dec. 13, 2023 (KR) 10-2023-0181158

(51) Int. Cl. H10N 60/20; G06N 10/40; H10N 60/82; H10N 69/00

(52) U.S. Cl. CPC H10N 60/20; H10N 60/82; H10N 69/00; G06N 10/40

(57) ABSTRACT

A superconductor-based quantum computer and an operating method thereof are disclosed. A superconductor-based quantum computer according to one embodiment includes a lower layer including a multi-chip module, a middle layer connected with the lower layer, and an upper layer connected with the middle layer. The upper layer includes a qubit layer, the middle layer includes a superconductor transmission line through which electromagnetic waves for controlling the qubit layer are transmitted, and a first coupling rate control element provided to adjust a coupling rate between the transmission line and the qubit layer. The first coupling rate control element includes a physically movable material layer, a boundary of which is movable depending on a voltage applied thereto, and a metal layer provided on a surface of the movable material layer, the metal layer facing the qubit layer and forming a capacitive coupling with the qubit layer and the transmission line.

### CROSS-REFERENCE TO RELATED APPLICATIONS

This application is based on and claims priority under 35 U.S.C. § 119 to Korean Patent Application No. 10-2023-0181158, filed on Dec. 13, 2023, in the Korean Intellectual Property Office, the disclosure of which is incorporated by reference herein in its entirety.

### BACKGROUND

### 1. Field

The disclosure relates to computers, and more particularly, to superconductor-based quantum computers and operating methods of the superconductor-based quantum computers.

### 2. Description of Related Art

A superconductor-based qubit system may include a transmon qubit part. The transmon qubit may consist of a coplanar capacitor and a Josephson junction, a control part to control and measure a qubit state, and a coupling part for coupling between qubits.

In terms of control, to control the state of a qubit more quickly and accurately, it is advantageous to increase a coupling rate between a qubit and a coplanar waveguide. However, if the coupling rate is too high, the qubit is electrically exposed to an external environment, which degrades the quality of the qubit (e.g., lifetime and quantum coherence time may be reduced). Likewise, in terms of coupling between qubits, there is a trade-off relationship between a speed of interaction between qubits and the quality of qubits, and the tradeoff depends on the coupling rate, and in the case of multiple qubits, crosstalk between qubits may additionally occur due to a combiner.

### SUMMARY

Provided are superconductor-based quantum computers capable of preventing quality degradation of a qubit.

Provided are superconductor-based quantum computers capable of preventing or minimizing crosstalk of qubits in a resting state.

Provided are operating methods of the superconductor-based quantum computer.

Additional aspects will be set forth in part in the description which follows and, in part, will be apparent from the description, or may be learned by practice of the presented embodiments of the disclosure.

According to an aspect of the disclosure, a superconductor-based quantum computer includes a lower layer including a multi-chip module, a middle layer provided above the lower layer and connected with the lower layer, and an upper layer provided on the middle layer and connected with the middle layer. The upper layer may include a qubit layer, the middle layer may include a superconductor transmission line through which electromagnetic waves for controlling the qubit layer are transmitted and a first coupling rate control element provided at a position corresponding to the qubit layer below the upper layer, spaced apart from the transmission line and the qubit layer, and provided to adjust the coupling rate between the transmission line and the qubit layer. The first coupling rate control element may include a movable material layer, a boundary of which is physically movable depending on a voltage applied thereto, and a metal layer provided on a surface of the movable material, the metal layer facing the qubit layer and forming a capacitive coupling with the qubit layer and the transmission line.

In one example, the first coupling rate control element may be included in the middle layer. In one example, the first coupling rate control element may be provided by a floating state of the movable material layer in the middle layer.

In one example, the qubit layer may include a first qubit layer and a second qubit layer spaced apart from each other, wherein the metal layer may include a first metal layer provided at a position corresponding to the first qubit layer and a second metal layer provided at a position corresponding to the second qubit layer.

In one example, the first coupling rate control element may be provided on the lower layer, may have a layer structure facing the qubit layer, and may be spaced apart from the middle layer. The metal layer may include a vertical rod protruding from the movable material layer toward the qubit layer. The qubit layer may include a first qubit layer and a second qubit layer spaced apart from each other, and the first coupling rate control element may be provided to correspond to the first qubit layer, and a second coupling rate control element may be provided to correspond to the second qubit layer, wherein the second coupling rate control element has the same layer structure as the layer structure of the first coupling rate control element. In one example, the movable material layer may include a piezoelectric material.

In one example, the movable material layer may include a material that exhibits electrokinetic movement in response to electrostatic force, electromagnetic force, piezoelectric force, and/or thermo-electric force.

In one example, the middle layer may include two base layers spaced apart from each other, the transmission line is provided on surfaces of the two base layers, and the first coupling rate control element is provided between the two base layers.

In one example, the lower layer, the middle layer, and the upper layer may be vertically connected with each other via bump balls.

In one example, the movable material layer and the metal layer may include the same material as each other.

According to an aspect of the disclosure, a method of operating a superconductor-based quantum computer, the method includes, with respect to a coupling rate control element that is at a given distance from a transmission line and a qubit layer before an operating voltage is applied to the coupling rate control element, adjusting a gap between the transmission line and/or qubit layer and the coupling rate control element by applying a first operating voltage to the coupling rate control element, wherein the coupling rate control element includes a movable material layer, a boundary of which is movable depending on an applied voltage, and a metal layer provided on a surface of the movable material layer facing the qubit layer and forming a capacitive coupling with the qubit layer and the transmission line.

In one example, the adjusting of the gap between the transmission line and/or qubit layer and the coupling rate control element may include moving the movable material layer closer to the transmission line and/or the qubit layer to strengthen the capacitive coupling.

In one example, the adjusting of the gap between the transmission line and/or qubit layer and the coupling rate control element may include moving the movable material layer away from the transmission line and/or the qubit layer so that the capacitive coupling is weakened.

In one example, the adjusting of the gap between the transmission line and/or qubit layer and the coupling rate control element may include expanding the movable material layer toward the transmission line and/or the qubit layer to strengthen the capacitive coupling.

In one example, the adjusting of the gap between the transmission line and/or qubit layer and the coupling rate control element may include contracting the movable material layer in a direction opposite to the transmission line and/or the qubit layer so that the capacitive coupling is weakened.

In one example, the qubit layer may include a plurality of qubit layers spaced apart from each other, and the coupling rate control element may include a plurality of coupling rate control elements corresponding to the plurality of qubit layers.

In the plurality of coupling rate control elements, a voltage for increasing the coupling rate between the first qubit layer and the transmission line may be applied to the first coupling rate control element corresponding to the first qubit layer selected for operation among the plurality of qubit layers.

A voltage for weakening the coupling rate between the second qubit layer and the transmission line may be applied to a second coupling rate control element corresponding to a second qubit layer that is in an idle state and does not participate in the operation among the plurality of qubit layers.

In one example, the metal layer may include a vertical rod layer protruding from the movable material layer toward the qubit layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a superconductor-based first quantum computer according to one or more embodiments;

FIG. 2 is a cross-sectional view illustrating expansion and contraction of a base layer (a movable material layer) of a coupling rate control element in the first quantum computer of FIG. 1;

FIG. 3A is a cross-sectional view showing a horizontal or vertical movement of the base layer (a movable material layer) of the coupling rate control element in the first quantum computer of FIG. 1;

FIG. 3B is a cross-sectional view showing vertical movements/positions of three coupling rate control elements which are disposed to one-to-one correspond to three pairs of qubit layers in a logical operation;

FIG. 4 is an equivalent circuit diagram of the first quantum computer of FIG. 1;

FIG. 5 is a cross-sectional view showing a second quantum computer, according to one or more embodiments;

FIG. 6 is a cross-sectional view showing a case in which a height of a vertical rod layer of the second coupling rate control element in the second quantum computer of FIG. 5 is increased (a gap between the vertical load layer and the qubit is reduced);

FIG. 7 is a cross-sectional view showing a case in which the height of the vertical rod layer of the second coupling rate control element in the second quantum computer of FIG. 5 is reduced (a gap between the vertical load layer and the qubit is increased); and

FIG. 8 is a cross-sectional view showing a case in which qubit layers and respectively corresponding coupling rate control elements are provided in the second quantum computer of FIG. 5.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Hereinafter, superconductor-based quantum computers and methods of operating the same according to embodiments will be described in detail with reference to the accompanying drawings. The operating methods are explained together in the process of explaining the quantum computers. In this process, the thicknesses of layers or regions shown in the drawings may be somewhat exaggerated for clarity of description.

First, superconductor-based quantum computers according to embodiments are described.

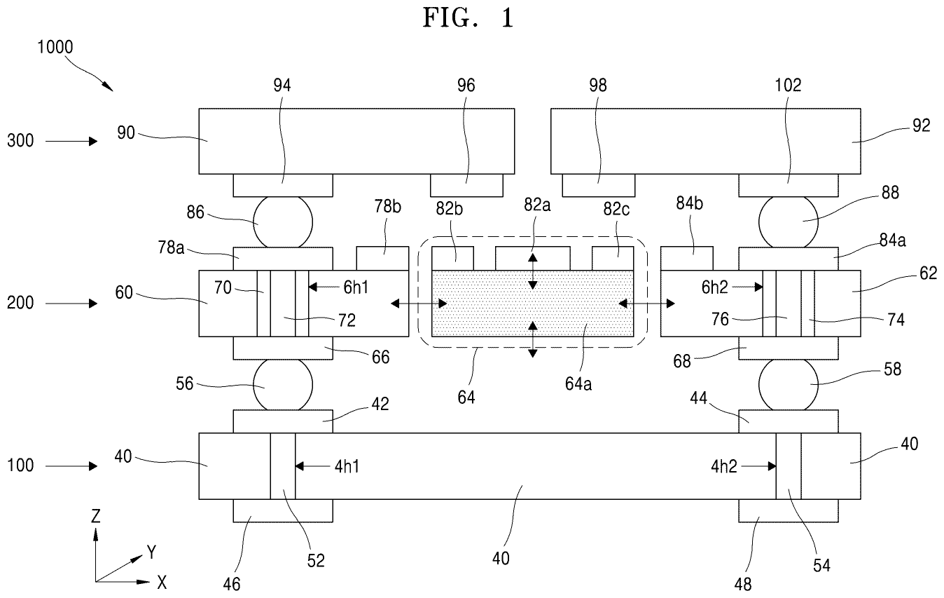

FIG. 1 is a cross-sectional view showing a superconductor-based first quantum computer 1000, according to one or more embodiments.

Referring to FIG. 1, the first quantum computer 1000 may include a lower layer 100, a middle layer 200, and an upper layer 300. The lower layer 100, the middle layer 200, and the upper layer 300 may be sequentially stacked in a direction perpendicular to a substrate (not shown) below the lower layer 100 (e.g., a Z-axis direction). The lower layer 100, the middle layer 200, and the upper layer 300 may also be referred to as a first layer, a second layer, and a third layer, respectively. The substrate may be parallel to the X-Y plane of FIG. 1. An upper surface of the substrate may be parallel to the X-Y plane, and the lower layer 100 may be formed on or connected with the upper surface of the substrate. The lower layer 100, the middle layer 200, and the upper layer 300 may be stacked in that order in the direction perpendicular to (and moving up/away from) the upper surface of the substrate (the Z-axis direction). In one example, the substrate may include a circuit related to an operation of the first quantum computer 1000. In one example, the circuit may be configured or disposed on the upper surface of the substrate. In one example, the substrate may include a semiconductor substrate or a non-semiconductor substrate (e.g., a substrate not including a semiconductor material, an insulating substrate, etc.). In one example, the substrate may include a printed circuit board (PCB). In one example, the circuit related to the operation of the first quantum computer 1000 may include a circuit related to writing data to a qubit (e.g., a transmon qubit) or reading or erasing data written to a qubit; other functions may be provided.

In one example, the lower layer 100 may be combined or connected with the substrate using a bump ball, but other combining or connecting means may be used. In one example, the lower layer 100 and the middle layer 200 may be electrically connected to each other, and the middle layer 200 and the upper layer 300 may be electrically connected to each other. The lower layer 100 and the upper layer 300 may not be in direct physical or electrical contact with each other. In one example, the lower layer 100 and the middle layer 200 may be connected to each other through first and second bump balls 56 and 58 that are spaced apart from each other. Other electrical connection methods or connection means may be used. In one example, the middle layer 200 and the upper layer 300 may be connected to each other through third and fourth bump balls 86 and 88 that are spaced apart from each other; other electrical connection means may be used. In one example, a material of the first to fourth bump balls 56, 58, 86, and 88 may include a superconducting material, as a non-limiting example, indium (In).

In one example, the lower layer 100 may include a multi-chip module that includes a circuit related to an operation of the middle layer 200. Therefore, the lower layer 100 may also be referred to as a multi-chip module layer. In one example, the lower layer 100 may include a first base layer 40. The first base layer 40 may be/include silicon or a silicon layer (silicon substrate) or may be/include a sapphire layer (sapphire substrate). The first base layer 40 may have a substantially constant thickness (Z dimension). In one example, first and second through-holes 4h1 and 4h2 are formed in the first base layer 40 and are spaced apart from each other. The first and second through-holes 4h1 and 4h2 may also be referred to as first and second via holes. The first through-hole 4h1 may be filled with a first conductive plug 52. The first through-hole 4h1 may be completely (or incompletely) filled with the first conductive plug 52. In one example, the first conductive plug 52 may be/include a metal, for nonlimiting example, copper (Cu). The first conductive plug 52 may include a superconducting material or superconducting material. The second through-hole 4h2 may be completely or incompletely filled with a second conductive plug 54. A material of the second conductive plug 54 may be the same as that of the first conductive plug 52. The material of the second conductive plug 54 may, but need not be, be the same as the first conductive plug 52 (or one of the same possible materials). First and second metal layers 42 and 44, which are spaced apart from each other, are provided on an upper surface of the first base layer 40. An upper surface of the first metal layer 42 may contact the first bump ball 56, and an upper surface of the second metal layer 44 may contact the second bump ball 58. In one example, the first metal layer 42 and the second metal layer 44 may be spaced apart from each other by a distance corresponding to the distance between the first conductive plug 52 and the second conductive plug 54. The first metal layer 42 may cover an upper end of the first through-hole 4h1 and the entire upper surface of the first conductive plug 52. The first metal layer 42 may be in direct contact with the entire upper surface of the first conductive plug 52 and may also be in direct contact with the first base layer 40 around the first conductive plug 52. The first metal layer 42 may include a superconducting material or may be a superconducting material layer. As an example, the first metal layer 42 may include a metal that exhibits superconductor characteristics at room temperature or sub-zero temperature, and the metal may include one of aluminum (Al), tantalum (Ta), and niobium (Nb) but is not limited thereto. In one example, the sub-zero temperature may be, in Celsius, from 0 degrees to −99 degrees, from −100 degrees to −150 degrees, from −150 degrees to −200 degrees, or from −200 degrees to −273 degrees.

The second metal layer 44 may cover the entire second through-hole 4h2 and the second conductive plug 54. The second metal layer 44 may be formed so that a portion of the second metal layer 44 covers the entire upper end (upper entrance) of the second through-hole 4h2 and to directly contact the entire upper surface of the second conductive plug 54. The second metal layer 44 may also be in direct contact with the first base layer 40 around the second conductive plug 54. In one example, the second metal layer 44 may include a superconducting material or may be a superconducting material layer. In one example, the second metal layer 44 may include a metal that exhibits superconductor characteristics at room temperature, or a sub-zero temperature described above. The material of the second metal layer 44 may be the same as, or different from, the material of the first metal layer 42. The thicknesses of the first and second metal layers 42 and 44 may be substantially the same or may differ.

Third and fourth metal layers 46 and 48 are provided on a lower surface of the first base layer 40. The third and fourth metal layers 46 and 48 are spaced apart from each other. The third and fourth metal layers 46 and 48 may be in direct contact with the lower surface of the first base layer 40.

The third and fourth metal layers 46 and 48 may be disposed at positions corresponding to the first and second metal layers 42 and 44, respectively (e.g., may be on a same line in the Z direction). The third metal layer 46 may be disposed to face the first metal layer 42 with the first base layer 40 and the first through-hole 4h1 therebetween. The entire lower end (lower opening) of the first through-hole 4h1 and the entire lower surface of the first conductive plug 52 may be covered with the third metal layer 46. The third metal layer 46 may be in direct contact with the entire lower surface of the first conductive plug 52. The third metal layer 46 may also be in direct contact with the lower surface of the first base layer 40 around the lower surface of the first conductive plug 52. In one example, the third metal layer 46 may include a superconducting material or may be a superconducting material layer. The third metal layer 46 may include a metal that exhibits superconductor characteristics at room temperature or the sub-zero temperature described above. The material of the third metal layer 46 may be the same as the material of the first metal layer 42 but is not limited thereto. Both the third metal layer 46 and the first metal layer 42 may include superconductor layers. The third metal layer 46 and the first metal layer 42 may include different superconducting materials.

The fourth metal layer 48 may be disposed below the second metal layer 44. In one example, the fourth metal layer 48 may be disposed to face the second metal layer 44 with the first base layer 40 and the second through-hole 4h2 therebetween. A portion of the fourth metal layer 48 may cover the entire lower end of the second through-hole 4h2 and the entire lower surface of the second conductive plug 54. The fourth metal layer 48 may be in contact with the entire lower surface of the second conductive plug 54 and may also be in contact with the lower surface of the first base layer 40 around the second conductive plug 54. The material characteristics of the fourth metal layer 48 may be the same as those of the third metal layer 46. The third and fourth metal layers 46 and 48 may include the same or different superconducting materials.

Widths of the first to fourth metal layers 42, 44, 46, and 48 in the horizontal direction (e.g., X-axis direction) may be the same or different from each other. For example, the first and second metal layers 42 and 44 may have the same width, the third and fourth metal layers 46 and 48 may have the same width, and the widths of the first and second metal layers 42 and 44 may be different from the widths of the third and fourth metal layers 46 and 48. In one example, the first and third metal layers 42 and 46 may have the same width, the second and fourth metal layers 44 and 48 may have the same width, and the widths of the first and third metal layers 42 and 46 may be different from the widths of the second and fourth metal layers 44 and 48.

Either of the upper and lower surfaces of the first base layer 40 may be referred to as a first surface, and the other may be expressed as a second surface.

In one example, the lower layer 100 may include a transmission line used to directly control and measure qubits included in the upper layer 300.

In one example, the lower layer 100 may include a pin holder that may accommodate an electrical pin to be directly connected to an external electrode.

In one example, the middle layer 200 is for control (e.g., state change, etc.) and measurement of a qubit layer of the upper layer 300 and may be referred to as a control chip.

The middle layer 200 may include second and third base layers 60 and 62 spaced apart from each other. The middle layer 200 may also include a first coupling rate control element 64 between the second base layer 60 and the third base layer 62. The first coupling rate control element 64 may be spaced apart from the second and third base layers 60 and 62 and not in physical contact with the second and third base layers 60 and 62. The material of the second base layer 60 may (but need not) be the same as the material of the first base layer 40. For example, both the first and second base layers 40 and 60 may be a silicon layer or a sapphire layer, or one may be a silicon layer and the other may be a sapphire layer. The material of the third base layer 62 may (but need not) be the same as that of the second base layer 60. In one example, thicknesses of the second and third base layers 60 and 62 may or may not be substantially the same.

The second base layer 60 may include a third through-hole 6h1. The second base layer 60 may be configured so that the third through-hole 6h1 is located directly above the first bump ball 56. The inner surface of the third through-hole 6h1 may be covered with a first insulating layer 70. The first insulating layer 70 may cover the entire inner surface of the third through-hole 6h1. The thickness of the first insulating layer 70 may be less than the radius of the third through-hole 6h1. A region remaining after the first insulating layer 70 is filled in the third through-hole 6h1, that is, the inner region surrounded by the first insulating layer 70, may be filled with a third conductive plug 72. The third conductive plug 72 may completely fill the inner region. As a result, the third through-hole 6h1 may be completely filled with the first insulating layer 70 and the third conductive plug 72. A material of the third conductive plug 72 may (but need not) be the same as the material of the first conductive plug 52.

A fifth metal layer 78a and a sixth metal layer 78b may be on an upper surface of the second base layer 60 and may be spaced apart from each other. The fifth and sixth metal layers 78a and 78b may be used as transmission lines and may function as resonators. The transmission line may be a waveguide through which an electromagnetic wave for qubit operation is transmitted. The electromagnetic wave may be a microwave. For example, the electromagnetic wave may include an electromagnetic wave with a frequency of 5 GHz or less.

The fifth metal layer 78a may cover the third through-hole 6h1, the first insulating layer 70, and the third conductive plug 72. In one example, the fifth metal layer 78a may be in contact with an entire upper surface of the first insulating layer 70 and an entire upper surface of the third conductive plug 72 and may be in contact with the upper surface of the base layer 60 around the third through-hole 6h1. An upper surface of the fifth metal layer 78a may be in contact with a third bump ball 86. The sixth metal layer 78b may be spaced apart from the third through-hole 6h1 and may be disposed between the fifth metal layer 78a and the first coupling rate control element 64. In one example, a material of the fifth and sixth metal layers 78a and 78b may include a superconducting material and may be the same as or different from the material of the first metal layer 42. Thicknesses of the fifth and sixth metal layers 78a and 78b may be the same or different.

A seventh metal layer 66 may be on the lower surface of the second base layer 60. The seventh metal layer 66 may face the first metal layer 42 with the first bump ball 56 therebetween. That is, in the vertical direction, the first metal layer 42, the first bump ball 56, and the seventh metal layer 66 may be arranged in that sequence. The seventh metal layer 66 may cover an entire lower entrance of the third through-hole 6h1, an entire lower surface of the first insulating layer 70, and the entire lower surface of the third conductive plug 72. The seventh metal layer 66 may be in direct contact with the entire lower surface of the first insulating layer 70 and the entire lower surface of the third conductive plug 72. A lower surface of the seventh metal layer 66 may be in contact with the first bump ball 56. The seventh metal layer 66, the third through-hole 6h1, and the fifth metal layer 78a are stacked in that order.

The third base layer 62 may include a fourth through-hole 6h2. The fourth through-hole 6h2 may be located above the second bump ball 58. A tenth metal layer 68 may be between the fourth through-hole 6h2 and the second bump ball 58. An entire inner surface (inner side surface) of the fourth through-hole 6h2 may be covered with a second insulating layer 74. The second insulating layer 74 may be in direct contact with the inner surface of the fourth through-hole 6h2. A thickness of the second insulating layer 74 in the horizontal direction may be less than the radius of the fourth through-hole 6h2 and the thickness may be substantially constant over the entire inner surface. An inner region of the second insulating layer 74 of the fourth through-hole 6h2 may be filled with a fourth conductive plug 76. In one example, the inner region of the second insulating layer 74 of the fourth through-hole 6h2 may be completely filled with the fourth conductive plug 76. As a result, the fourth through-hole 6h2 may be completely filled with the second insulating layer 74 and the fourth conductive plug 76. A material of the fourth conductive plug 76 may be the same as or different from the material of the third conductive plug 72. A material of the second insulating layer 74 may be the same as or different from the material of the first insulating layer 70.

Eighth and ninth metal layers 84a and 84b are provided on an upper surface of the third base layer 62 and are spaced apart from each other. The ninth metal layer 84b may be between the eighth metal layer 84a and the first coupling rate control element 64. A thickness of the eighth metal layer 84a and a thickness of the ninth metal layer 84b may be substantially the same or different from each other. In one example, the material of the eighth and ninth metal layers 84a and 84b may include a superconducting material and may be the same as or different from the material of the first metal layer 42. An upper surface of the eighth metal layer 84a may be in contact with a fourth bump ball 88. The eighth metal layer 84a may cover an entire upper entrance of the fourth through-hole 6h2. The eighth metal layer 84a may cover an entire upper surface of the second insulating layer 74 and an entire upper surface of the fourth conductive plug 76. A lower surface of the eighth metal layer 84a may be in direct contact with the entire upper surface of the second insulating layer 74 and the entire upper surface of the fourth conductive plug 76. As a result, the eighth metal layer 84a may be located between the fourth conductive plug 76 and the fourth bump ball 88 and may be in direct contact with both the fourth conductive plug 76 and the fourth bump ball 88. The fourth conductive plug 76, the eighth metal layer 84a, and the fourth bump ball 88 are stacked in that order.

The tenth metal layer 68 is provided on a lower surface of the third base layer 62. The tenth metal layer 68 may be in direct contact with the lower surface of the third base layer 62. The tenth metal layer 68 may cover an entire lower entrance of the fourth through-hole 6h2, an entire lower surface of the second insulating layer 74, and an entire lower surface of the fourth conductive plug 76. The tenth metal layer 68 may be in direct contact with the entire lower surface of the second insulating layer 74 and the entire lower surface of the fourth conductive plug 76. The second metal layer 44, the second bump ball 58, and the tenth metal layer 68 may be stacked in that order. The material of the tenth metal layer 68 may be the same as the material of the first metal layer 42. Among the materials that may be used as the material of the first metal layer 42, the materials for the first and tenth metal layers 42 and 68 may differ from each other.

The first coupling rate control element 64 may include a fourth base layer 64a and eleventh to thirteenth metal layers 82a, 82b, and 82c arranged to be spaced apart from each other on an upper surface of the fourth base layer 64a. In one example, the first coupling rate control element 64 may be in a floating (suspended) state between the second base layer 60 and the third base layer 62 but is not limited thereto. For this purpose, the first coupling rate control element 64 may include a portion (a branch) extending in a direction perpendicular to the cross-section view of FIG. 1 (e.g., in the Y-axis direction), and the extended portion may be connected to a support layer. The extended portion may be referred to as a support arm of the first coupling rate control element 64.

The fourth base layer 64a may include a surface (e.g., side surface, upper surface, lower surface) that may be moved depending on a voltage/current applied to the fourth base layer 64a through at least some of the eleventh to thirteenth metal layers 82a, 82b, and 82c and may include materials that may exhibit an electrokinetic effect. The fourth base layer 64a may expand or contract by the applied voltage or may be moved in a given direction (e.g., laterally, upwardly or downwardly) by the applied voltage. Accordingly, a position of the surface of the fourth base layer 64a may be moved from a position when voltage/current is not applied.

Because the voltage/current applied to the first coupling rate control element 64 is controlled due to the electrokinetic effect (e.g., movement/distortion) of the fourth base layer 64a, a gap between the first coupling rate control element 64 and a layer next to the first coupling rate control element 64 may be adjusted. For example, if a voltage is applied to the twelfth and thirteenth metal layers 82b and 82c, the fourth base layer 64a may expand in a horizontal and/or vertical directions depending on the material and shape of the fourth base layer 64a. Accordingly, a gap (distance) between the first coupling rate control element 64 and the second and third base layers 60 and 62 and/or a gap (distance) between the first coupling rate control element 64 and first and second qubit layers 96 and 98 provided on a lower surface of the upper layer 300 may be closer each other or farther apart from each other than in case when the voltage/current is not applied.

Depending on the material and shape of the fourth base layer 64a, the first coupling rate control element 64 itself may be moved in the horizontal or vertical direction. Accordingly, the gaps between the first coupling rate control element 64 and the nearby layers 60, 62, 96, and 98 may be different from when no voltage/current is applied to the first coupling rate control element 64. In an initial state in which no voltage/current is applied to the first coupling rate control element 64, the gaps (distances) between the first coupling rate control element 64 and the adjacent layers 60, 62, 96, and 98 may be referred to as reference gaps (distances), initial gaps (distances), or initially set gaps (distances). In the horizontal direction, the reference gap may be a gap between the fourth base layer 64a and the second and third base layers 60 and 62, a gap between the twelfth metal layer 82b and the sixth metal layer 78b, or a gap between the thirteenth metal layer 82c and the ninth metal layer 84b. The reference gap in the vertical direction may be a gap between some of the eleventh to thirteenth metal layers 82a, 82b, and 82c and the first and second qubit layers 96 and 98.

In one example, when a voltage/current is applied to the first coupling rate control element 64 in an operation of the first quantum computer 1000, a maximum moving distance of the first coupling rate control element 64 in a given direction is less than the reference gap in that direction. The maximum moving gap may be a maximum distance by which the first coupling rate control element 64 itself is moved horizontally and/or vertically. If the first coupling rate control element 64 itself is not moved, but rather a surface (e.g., side surface, upper surface, lower surface) of the fourth base layer 64a is moved in a vertical direction with respect to the surface according to expansion or contraction of the fourth base layer 64a, the maximum moving gap may be a maximum expansion distance or a maximum contraction distance. For example, when the fourth base layer 64a expands in the horizontal direction, a side surface of the fourth base layer 64a may get closer to the adjacent second and third base layers 60 and 62 as much as the maximum movement distance, and when the fourth base layer 64a contracts in the horizontal direction, the side surface of the fourth base layer 64a may move away from the adjacent second and third base layers 60 and 62 as much as the maximum movement distance. In one example, when the fourth base layer 64a itself is moved horizontally, the fourth base layer 64a may be moved to the third base layer 62 as much as the maximum movement distance in the horizontal direction (e.g., X-axis direction), while the fourth base layer 64a may be moved away from the second base layer 60 as much as the maximum moving distance.

In one example, the maximum moving distance may be set to 1 μm or less, but is not limited thereto. For example, if the reference gap changes, the setting for the maximum movement distance may also be changed.

In one example, if the gap between (i) the first coupling rate control element 64 and (ii) the second and third base layers 60 and 62 and the first and second qubit layers 96 and 98 (hereinafter, adjacent layers 60, 62, 96, and 98) is away from the reference gap by as much as the maximum movement distance, the coupling rate between the first coupling rate control element 64 and the adjacent layers 60, 62, 96, and 98 may be considered substantially zero. Therefore, if two or more qubit layers are aligned to participate (be used) in a logical operation, a coupling rate control element corresponding to the qubit layer directly used in the logical operation is moved closer to an adjacent layer(s) within the maximum movement distance range, thereby increasing the coupling rate of the qubit layer. However, to prevent the quality (e.g., lifetime, quantum coherence time, or time for which the quantum entanglement state is maintained) of the qubit layer directly used in a logical operation from being degraded, the coupling rate of the corresponding qubit layer should not exceed a set coupling rate. The coupling rate control element corresponding to the remaining qubit layers that are not used in the operation, that is, the qubit layers in an idle state during the operation may be moved further away from the qubit layers than the reference gap, thereby, reducing the coupling rate for the remaining qubit layers. For example, the coupling rate control element corresponding to the qubit layers in the idle state during the operation may be moved further away from the qubit layers by the maximum movement distance, and thus, the coupling rate for the remaining qubit layers may be substantially zero. Accordingly, during the operation, the quality of the remaining qubit layers that are not involved in the operation may be prevented from degrading, and crosstalk of the remaining qubit layers may also be prevented.

Because a surface of the fourth base layer 64a may be moved or the fourth base layer 64a itself may be moved depending on a voltage/current applied to the first coupling rate control element 64, the fourth base layer 64a may be referred to as a moving base layer or a movable base layer. The first coupling rate control element 64 may be said to be a movable coupling rate control element.

A dielectric layer (e.g., an air layer or other insulating material) may be present or disposed between the first coupling rate control element 64 and the adjacent layers 60, 62, 96, and 98, metal layers 78b and 84b may be present on the first coupling rate control element 64 and the adjacent layers 60 and 62, and the first and second qubit layers 96 and 98 may include metal layers, thus, as a result, the movement of the first coupling rate control element 64 as described above may change a capacitance between the first coupling rate control element 64 and the adjacent layers 60, 62, 96, and 98. As an example, the capacitance between the twelfth and thirteenth metal layers 82b and 82c and the adjacent layers 60, 62, 96, and 98 may be changed by moving the first coupling rate control element 64.

The change in capacitance may affect a coupling rate between the first and second qubit layers 96 and 98 and the transmission lines (coplanar waveguide) (e.g., 78b and 84b) of the middle layer 200, and as a result, the coupling rate for the first and second qubit layers 96 and 98 may be adjusted by controlling a voltage applied to the first coupling rate control element 64. As an example, by applying a voltage/current to the first coupling rate control element 64 so that the gap between the first coupling rate control element 64 and the adjacent layers 60, 62, 96, and 98 is increased, the coupling rate for the first and second qubit layers 96 and 98 may be reduced. Conversely, when a voltage is applied to the first coupling rate control element 64 so that the gap becomes smaller, the coupling rate for the first and second qubit layers 96 and 98 may be increased.

As the coupling rate for the first and second qubit layers 96 and 98 increases, a state control (e.g., state change, state read) for the first and second qubit layers 96 and 98 may be performed quickly and accurately, but if the coupling rate increases above a set value, the possibility of electrically exposing the state of the first and second qubit layers 96 and 98 to an external environment may increase, and as a result, the quality of the first and second qubit layers 96 and 98 may deteriorate.

Considering this point, the coupling rate for the first and second qubit layers 96 and 98 may be set in a range that does not deteriorate the quality of the first and second qubit layers 96 and 98, and the voltage applied to the first coupling rate control element 64 may also be set in a range that does not exceed the set coupling rate.

In one example, if a qubit array includes two or more qubits, one movable base layer, such as the fourth base layer 64a, may correspond to each two adjacent qubits. Therefore, with respect to the movable base layer corresponding to the qubit (qubit pair) selected for operation in the qubit array, the coupling rate of the selected qubit may be increased greater than a reference coupling rate by increasing a capacitance by reducing a gap between the movable base layer and layers adjacent to the movable base layer. For the movable base layer corresponding to a qubit in an idle state (the qubit is not the selected qubit) in the qubit array, the coupling rate of the qubit in the idle state may be reduced less than the reference coupling rate by reducing a capacitance by widening the gap between the adjacent layers and the movable base layer. The reference coupling rate is the qubit coupling rate when no voltage/current is applied to the movable base layer.

In the qubit array, by maintaining the coupling rate of an unselected and idle qubit lower than the reference coupling rate while the selected qubit is operating, for example, by maintaining the coupling rate low enough to be considered zero, while the selected qubit is in operation, the quality of the qubit in the idle state may be prevented from degrading, and crosstalk of the qubit in the idle state may also be prevented.

The qubit array may configure a logical qubit, and due to the movable base layer, the quality of the qubit in an idle state is not reduced and crosstalk of the quit in the idle state may also be reduced or prevented, thus, the number of qubits included in the logical qubit may be equal to the number (hereinafter referred to as the reference number of qubits) of qubits designed (set) under the assumption that the quality of the qubits in the idle state does not deteriorate.

If the qubit array does not include a movable base layer, that is, in the case of a previous type of logical qubit, the quality of the qubits in an idle state may deteriorate and crosstalk may occur. Therefore, in the case of a previous logical qubit, a number of qubits greater than the reference number of qubits may be included in consideration of the deterioration in quality of qubits in an idle state.

In the case of the quantum computer illustrated in this disclosure, the number of qubits constituting the logical qubit may be reduced as compared to previous quantum computers, and thus, the size of the quantum computer of the disclosure may be reduced.

In one example, the fourth base layer 64a may include a material that may exhibit an electrokinetic effect in response to electrostatic, electromagnetic, piezoelectric, and/or thermal-electric forces. As an example, the fourth base layer 64a may include a material that may be physically transformed (e.g., distorted or warped in one or more dimensions) when a voltage is applied, that is, a material that may exhibit a piezoelectric effect, for example, AlN, PZT, and TiN, but is not limited thereto. As an example, the fourth base layer 64a may include a metal that exhibits the electrokinetic effect. The metal may be a superconducting metal and may include a metal that may be used as the first metal layer 42 but is not limited thereto.

In one example, power (e.g., direct current power) may be transmitted to the fourth base layer 64a through a specific pin. In one example, an element (e.g., lever or torsion spring, etc.) for moving the fourth base layer 64a in the vertical direction may further be included.

In one example, in a state where no voltage is applied to the fourth base layer 64a, the width of the fourth base layer 64a in the horizontal and vertical directions may be constant. In other words, the fourth base layer 64a may have a symmetrical structure with respect to virtual vertical and horizontal lines passing through the center of the fourth base layer 64a.

In one example, the geometry of the fourth base layer 64a may be asymmetric depending on the material used as the fourth base layer 64a. For example, if the fourth base layer 64a is a metal layer including the metal, the fourth base layer 64a may have an asymmetric structure with respect to the virtual vertical line and/or horizontal line. In one example, a thickness of the fourth base layer 64a may or may not be the same as the thickness of the second and/or third base layers 60 and 62.

The eleventh to thirteenth metal layers 82a, 82b, and 82c formed on the fourth base layer 64a may include a superconducting metal but are not limited thereto. The eleventh to thirteenth metal layers 82a, 82b, and 82c may or may not have the same thickness. Materials of some of the eleventh to thirteenth metal layers 82a, 82b, and 82c may be different from the rest. The twelfth metal layer 82b may be disposed relatively adjacent to the first qubit layer 96, and the thirteenth metal layer 82c may be disposed relatively adjacent to the second qubit layer 98. The horizontal (X-dimension) width of the eleventh metal layer 82a may be greater than the width of the twelfth and thirteenth metal layers 82b and 82c. The vertical thickness of the eleventh to thirteenth metal layers 82a, 82b, and 82c may (but need not) be the same as the thickness of the adjacent metal layers 78b and 84b.

The upper layer 300 may be a layer on which the first and second qubit layers 96 and 98 (layers where data are recorded) are formed and may be referred to as a qubit chip. In one example, the first and second qubit layers 96 and 98 may be superconductor qubit layers and may include a transmon qubit including a capacitor and a Josephson element (Josephson junction).

In one example, the upper layer 300 may include a fifth base layer 90 and a sixth base layer 92 spaced apart from each other. In one example, materials of the fifth and sixth base layers 90 and 92 may be the same as or different from those of the first base layer 40. The thicknesses of the fifth and sixth base layers 90 and 92 may be the same or different from each other. In one example, the fifth and sixth base layers 90 and 92 may be at the same height (Z dimension) and arranged parallel to each other (in an X-Y plane). The fifth and sixth base layers 90 and 92 may be arranged parallel or substantially parallel to the base layers 60, 62, and 64a included in the middle layer 200.

In one example, fourteenth and fifteenth metal layers 94 and 96 are formed on a lower surface of the fifth base layer 90 to be spaced apart from each other. A portion of the lower surface of the fifth base layer 90 may face the second base layer 60, and the remainder of the lower surface of the fifth base layer 90 may face the fourth base layer 64a. The fourteenth metal layer 94 may be above the fifth metal layer 78a. A lower surface of the fourteenth metal layer 94 may directly contact the third bump ball 86. The fourteenth metal layer 94 may be disposed to face the fifth metal layer 78a with the third bump ball 86 therebetween. The fifth metal layer 78a, the third bump ball 86, and the fourteenth metal layer 94 may form a layer structure in which the fifth metal layer 78a, the third bump ball 86, and the fourteenth metal layer 94 are sequentially stacked in that order. The fifteenth metal layer 96 may be disposed above the twelfth metal layer 82b included in the first coupling rate control element 64. The fifteenth metal layer 96 and the twelfth metal layer 82b are spaced apart from each other, and a space between the fifteenth metal layer 96 and the twelfth metal layer 82b may be filled with air or another dielectric.

In one example, the fifteenth metal layer 96 may include one transmon qubit (capacitor+Josephson element) and may be referred to as the first qubit layer 96. The fifteenth metal layer 96 may be a material layer in which two different types of data (e.g., data corresponding to bit 0 or bit 1) or two different quantum states may coexist and may include a superconducting material. The quantum state of the fifteenth metal layer 96 may be controlled and measured using electromagnetic waves (e.g., microwaves) transmitted through a transmission line included in the middle layer 200, which is a control chip/layer. In one example, the fifteenth metal layer 96 may be disposed on the lower surface of the fifth base layer 90 without physically contacting other surrounding material layers, and may be an electrically independent layer, but is not limited thereto. Material of the fourteenth and fifteenth metal layers 94 and 96 may or may not be the same as the material of the first metal layer 42.

A sixteenth metal layer 98 and a seventeenth metal layer 102 may be on a lower surface of the sixth base layer 92 and may be spaced apart from each other. In one example, the sixteenth metal layer 98 may include one qubit layer in which data is written. The sixteenth metal layer 98 may be referred to as the second qubit layer 98. The sixteenth metal layer 98 may also include a material layer in which two different data or two different quantum states may coexist. The material of the sixteenth metal layer 98 may or may not be the same as the material of the fifteenth metal layer 96. The sixteenth metal layer 98 may be disposed above the thirteenth metal layer 82c of the first coupling rate control element 64 but is not limited to this. An air layer or another dielectric material layer may exist between the sixteenth metal layer 98 and the thirteenth metal layer 82c. Like the fifteenth metal layer 96, the sixteenth metal layer 98 may also be a completely independent or isolated layer from the lower surface of the sixth base layer 92.

In one example, the seventeenth metal layer 102 may be disposed above the eighth metal layer 84a. A lower surface of the seventeenth metal layer 102 may be in contact with the fourth bump ball 88. The seventeenth metal layer 102 may be disposed to face the eighth metal layer 84a vertically with the fourth bump ball 88 therebetween. As a result, the eighth metal layer 84a, the fourth bump ball 88, and the seventeenth metal layer 102 may form a layer structure in which the eighth metal layer 84a, the fourth bump ball 88, and the seventeenth metal layer 102 are stacked in the stated order. In one example, the seventeenth metal layer 120 may be a superconducting material and may be the same as or different from the material of the sixteenth metal layer 98.

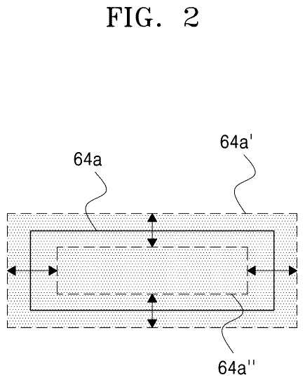

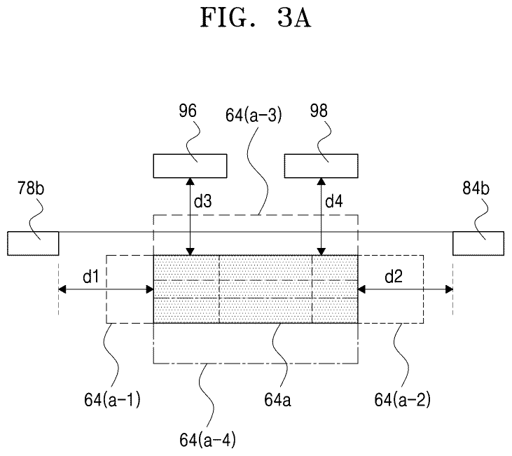

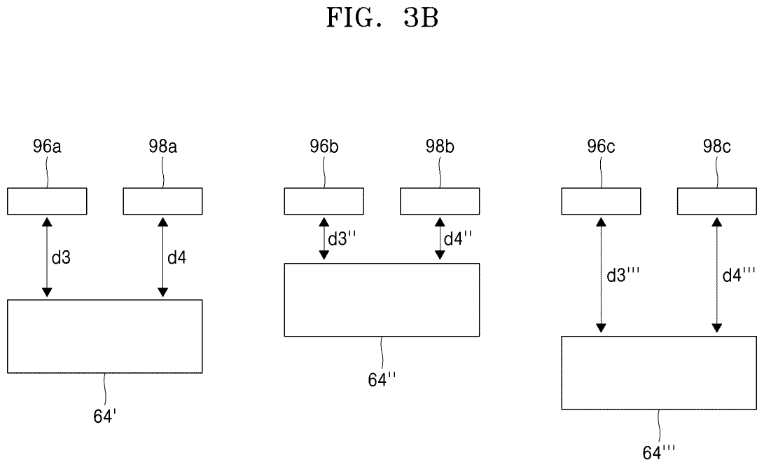

FIG. 2, FIG. 3A illustrate movement of the first coupling rate control element 64 or expansion and contraction deformation of the fourth base layer 64a according to a voltage applied to the first coupling rate control element 64 of FIG. 1. For convenience of illustration, the metal layers 82a, 82b, and 82c formed on the fourth base layer 64a are not shown.

FIG. 2 illustrates a case that, when the fourth base layer 64a includes a piezoelectric material, the fourth base layer 64a has a degree of expansion or contraction deformation in the horizontal or vertical direction depending on a voltage applied to the first coupling rate control element 64.

In FIG. 2, reference numeral 64a′ represents the fourth base layer as expanded when a first voltage is applied to the first coupling rate control element 64. Reference numeral 64a″ represents the fourth base layer as contracted according to a second voltage applied to the first coupling rate control element 64.

FIG. 3A shows a case when the fourth base layer 64a itself is moved in the horizontal or vertical direction as a voltage is applied to the first coupling rate control element 64. The degree of movement in each direction may be proportional to the applied voltage.

In FIG. 3A, a first reference gap d1 represents a gap between the fourth base layer 64a and the sixth metal layer 78b at a reference position before the first voltage is applied to the first coupling rate control element 64. The second reference gap d2 represents a gap between the fourth base layer 64a and the ninth metal layer 84b at the reference position. A third reference gap d3 represents a gap between the fourth base layer 64a and the first qubit layer 96 at the reference position. A fourth reference gap d4 represents a gap between the fourth base layer 64a and the second qubit layer 98 at the reference position.

In FIG. 3A, reference number 64(a−1) represents the fourth base layer moved to the left from the reference position while a third voltage is applied to the first coupling rate control element 64. While the third voltage is applied, a gap between the fourth base layer 64(a−1) and the sixth metal layer 78b becomes less than the first reference gap d1, and a gap between the fourth base layer 64(a−1) and the ninth metal layer 84b becomes greater than the second reference gap d2.

Reference number 64(a−2) indicates the fourth base layer moved to the right from the reference position as a fourth voltage is applied to the first coupling ratio control element 64. As the fourth voltage is applied, a gap between the fourth base layer 64(a−2) and the ninth metal layer 84b becomes less than the second reference gap d2, and a gap between the fourth base layer 64(a−2) and the sixth metal layer 78b becomes greater than the first reference interval d1.

Reference numeral 64(a−3) represents the fourth base layer moved upward from the reference position as a fifth voltage is applied to the first coupling ratio control element 64. As the fifth voltage is applied, a gap between the fourth base layer 64(a−3) and the first and second qubit layers 96 and 98 is less than the third and fourth reference gap d3 and d4.

Reference numeral 64(a−4) represents the fourth base layer moved downward from the reference position as a sixth voltage is applied to the first coupling rate control element 64. As the sixth voltage is applied, a gap between the fourth base layer 64(a−4) and the first and second qubit layers 96 and 98 becomes greater than the third and fourth reference gap d3 and d4.

In one example, the magnitudes and/or directions (polarities) of the third to sixth voltages may be different from each other but are not limited thereto.

In one example, by applying a seventh voltage different from the third to sixth voltages to the first coupling rate control element 64, the fourth base layer 64a may be moved in both the horizontal and vertical directions, that is, in a diagonal direction.

In one example, to control the coupling rate for the first and second qubit layers 96 and 98, the fourth base layer 64a may be moved in an arbitrary direction, and after completing a given operation of the quantum computer, a voltage for moving the fourth base layer 64a to the reference position may be applied to the first coupling rate control element 64.

FIG. 3B is a cross-sectional view showing vertical movements/positions of three distinct coupling rate control elements 64′, 64″, and 64″, in an example of the quantum computer. The rate control elements 64′, 64″, and 64″ may be arranged for logical operation with respectively corresponding pairs of qubit layers 96a-98b, 96b-98b, and 96c-98c. As indicated by the differences among the third and fourth reference gaps d3 and d4, d3″ and d4″, and d3″ and d4″, multiple rate control elements may be individually positioned for coordinated operation using multiple corresponding qubit layers of the quantum computer.

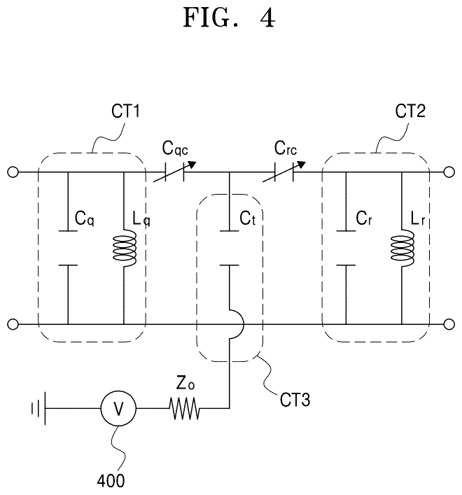

FIG. 4 shows an equivalent circuit of the first quantum computer 1000 illustrated in FIG. 1, according to one or more embodiments.

In FIG. 4, a first circuit unit CT1 may correspond to the first qubit layer 96 or the second qubit layer 98 of the upper layer 300, a second circuit unit CT2 may correspond to a portion of the middle (control chip) 200 excluding the first coupling rate control element 64, and a third circuit unit CT3 may correspond to the first coupling rate control element 64 of the middle layer 200.

The first circuit unit CT1 may form a first LC resonance circuit by including one capacitor C_{q} (hereinafter, qubit capacitor) and one reactance L_{q} (hereinafter, qubit reactance). The second circuit unit CT2 may form a second LC resonance circuit by including a first capacitor Cᵣ and a first reactance Lᵣ. The third circuit unit CT3 includes a second capacitor Cₜ. The third circuit unit CT3 is connected to a power source 400. The power source 400 may apply a voltage to the twelfth and thirteenth metal layers 82b and 82c provided on the fourth base layer 64a of the first coupling rate control element 64.

A third capacitor C_{qc} exists between the first circuit unit CT1 and the third circuit unit CT3, and a fourth capacitor C_{rc} exists between the second circuit unit CT2 and the third circuit unit CT3. The third capacitor C_{qc} is connected in series with the first circuit unit CT1 and the fourth capacitor C_{rc}. The fourth capacitor C_{rc} is connected in series with the second circuit unit CT2. The third circuit unit CT3 is connected between the third capacitor C_{qc} and the fourth capacitor C_{rc}.

The third capacitor C_{qc} may be formed by the first coupling rate control element 64, the first qubit layer 96, and a dielectric between the first coupling rate control element 64 and the first qubit layer 96. Also, the third capacitor C_{qc} may be formed by the first coupling rate control element 64, the second qubit layer 98, and a dielectric between the first coupling rate control element 64 and the second qubit layer 98.

The fourth capacitor C_{rc} may be formed by the sixth metal layer 78b, the first coupling rate control element 64, and a dielectric between the first coupling rate control element 64 and the sixth metal layer 78b adjacent thereto. Also, the fourth capacitor C_{rc} may be formed by the ninth metal layer 84b, the first coupling rate control element 64, and a dielectric between the first coupling rate control element 64 and the ninth metal layer 84b adjacent thereto.

As may be seen in FIG. 4, because the first coupling rate control element 64 (i.e., the third circuit unit CT3) has a capacitive coupling relationship with the first and second circuit units CT1 and CT2, the effective coupling rate of the first and second circuit units CT1 and CT2 may vary depending on the change in capacitance of the capacitors C_{qc} and C_{rc}.

As an example, referring to FIGS. 3A and 4 together, in FIG. 3A, the fourth base layer 64a may be considered to be the first coupling rate control element 64. When the fourth base layer 64a is moved downward (as indicated by reference number 64(a−4)), a distance between the fourth base layer 64a and the sixth and ninth metal layers 78b and 84b is further away than before the fourth base layer 64a is moved, and a distance between the fourth base layer 64a and the first and second qubit layers 96 and 98 is also further away than before the fourth base layer 64a is moved. This increase in the distance between electrodes facing each other corresponds to changes in the third and fourth capacitors C_{qc} and C_{rc}. Specifically, the capacitance of the third and fourth capacitors C_{qc} and C_{rc} decreases, and as a result, the effective coupling rate of the first and second circuit units CT1 and CT2, that is, the effective coupling rate between the first and second qubit layers 96 and 98 of the upper layer 300 and the transmission lines (e.g., 78b and 84b) of the middle layer 200 is lowered.

Conversely, when the fourth base layer 64a is moved upward from the reference position (as indicated by reference number 64(a−3)), a gap between the fourth base layer 64a and the first and second qubit layers 96 and 98 becomes less than before the fourth base layer 64a is moved. This decrease in the distance between the electrodes facing each other corresponds to changes in the third capacitor C_{qc}, specifically, the capacitance of the third capacitor C_{qc} increases, and as a result, the effective coupling rate of the first and second circuit units CT1 and CT2, that is, the effective coupling rate between the first and second qubit layers 96 and 98 of the upper layer 300 and the transmission lines (e.g., 78b and 84b) of the middle layer 200 increases.

As a result, by controlling the capacitance of the third and/or fourth capacitors C_{qc} and C_{rc} existing between the first and second circuit units CT1 and CT2, the effective coupling rate between the first and second circuit units CT1 and CT2 may be adjusted. Therefore, the coupling rate for selected qubits used in a specific operation in an operation of multiple qubits may be increased to a maximum set value yet remaining within a range in which the quality of the selected qubit does not deteriorate, and the coupling rates of the qubits not selected in the specific operation are maintained lower than a coupling rate of a previous qubit in an idle state. Accordingly, target operations (e.g., state control, measurement, etc.) may be performed quickly and accurately for the selected qubits without (or with minimal) quality degradation, while preventing quality degradation and crosstalk for the qubits in the idle state.

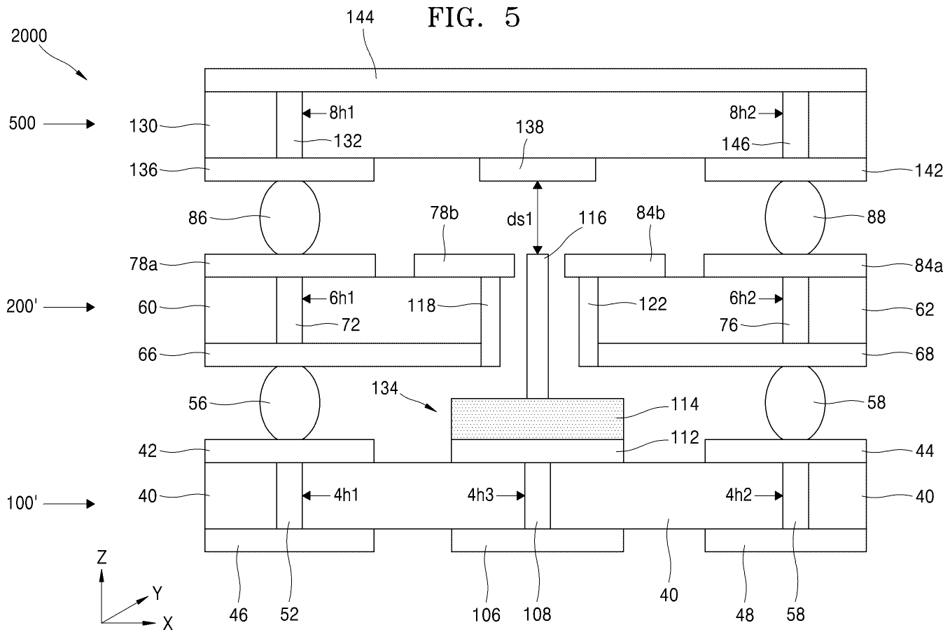

FIG. 5 shows a second quantum computer 2000, according to one or more embodiments.

Only parts that are different from the first quantum computer 1000 in FIG. 1 will be described.

Referring to FIG. 5, a second coupling rate control element 134 may be on an upper surface of a first base layer 40 of a lower layer 100′. The second coupling rate control element 134 may be disposed between and spaced apart from a first metal layer 42 and a second metal layer 44. The second coupling rate control element 134 may be connected to the eighteenth metal layer 106 (which is provided on a lower surface of the first base layer 40). A seventh through-hole 4h3 may be formed in the first base layer 40 between the eighteenth metal layer 106 and the second coupling rate control element 134. The seventh through-hole 4h3 may be filled with a seventh conductive plug 108. The eighteenth metal layer 106 and the second coupling rate control element 134 may be connected to each other through the seventh conductive plug 108. In one example, a material of the seventh conductive plug 108 may be the same as or different from the material of the first conductive plug 52. The second coupling rate control element 134 may include a nineteenth metal layer 112 on an upper surface of the first base layer 40, a seventh base layer 114 on the nineteenth metal layer 112, and a vertical rod layer 116 on the seventh base layer 114. That is, the nineteenth metal layer 112, the seventh base layer 114, and the vertical rod layer 116 included in the second coupling rate control element 134 are arranged in that order in the vertical direction on the upper surface of the first base layer 40. The nineteenth metal layer 112 may completely cover the seventh through-hole 4h3 and the seventh conductive plug 108 and may be in contact with an entire upper surface of the seventh conductive plug 108. The eighteenth metal layer 106 and the nineteenth metal layer 112 may be parallel to each other and may face each other with the seventh through-hole 4h3 therebetween. Horizontal widths of the eighteenth and nineteenth metal layers 106 and 112 may or may not be the same. The eighteenth and nineteenth metal layers 106 and 112 may include a superconducting material and may be the same as the material of the first metal layer 42 (but may include a superconducting material different from the material of the first metal layer 42). The seventh base layer 114 may cover an entire upper surface of the nineteenth metal layer 112, and a lower surface of the seventh base layer 114 may be in contact with the entire upper surface of the nineteenth metal layer 112. The electro-physical properties and materials of the seventh base layer 114 may be the same as those of the fourth base layer 64a but are not limited thereto. The seventh base layer 114 may be spaced apart from the seventh and tenth metal layers 66 and 68 of a middle layer 200′.

A horizontal width of the vertical rod layer 116 is less than a vertical length thereof. That is, an aspect ratio of the vertical rod layer 116 may be greater than 1. The vertical rod layer 116 may be located between the second and third base layers 60 and 62 and may be arranged to be spaced apart from the second and third base layers 60 and 62. The vertical rod layer 116 may be spaced upwardly from an upper layer 500 and apart from all metal layers (e.g., 138) attached to the upper layer 500. An upper end of the vertical rod layer 116 or a height of the vertical rod layer 116 may be equal to or higher or lower than a height of upper surfaces of the second and third base layers 60 and 62. In one example, the height of the vertical rod layer 116 may be the same as the height of the adjacent sixth and ninth metal layers 78a and 84b.

A side of the second base layer 60 adjacent to the vertical rod layer 116 may be covered with a twentieth metal layer 118. The twentieth metal layer 118 may be in contact with the sixth and seventh metal layers 78b and 66. The seventh and twentieth metal layers 66 and 118 may be formed as a single layer connected to each other, or, the sixth, seventh, and twentieth metal layers 78b, 66 and 118 may be formed as a single layer connected to each other. A material of the twentieth metal layer 118 may or may not be the same as the material of the seventh metal layer 66. The twentieth metal layer 118 and the vertical rod layer 116 are separated from each other.

A side surface of the third base layer 62 adjacent to the vertical rod layer 116 may be covered with a twenty-first metal layer 122 and may be in contact with the corresponding side surface. The twenty-first metal layer 122 may contact the ninth and tenth metal layers 84b and 68. The tenth and twenty-first metal layers 68 and 122 may be formed as a single connected layer, or, the ninth, tenth, and twenty-first metal layers 84b, 68 and 122 may be formed as a single connected layer. A material of the twenty-first metal layer 122 may be the same as the material of the tenth metal layer 68 but is not limited thereto. The twenty-first metal layer 122 and the vertical rod layer 116 are separated from each other. The twentieth metal layer 118 and the twenty-first metal layer 122 may face each other with the vertical rod layer 116 therebetween.

The upper layer 500 includes an eighth base layer 130, twenty-second to twenty-fourth metal layers 136, 138, and 142 on a lower surface of the eighth base layer 130 to be spaced apart from each other, and a twenty-fifth metal layer 144 on an upper surface of the eighth base layer 130. The twenty-second metal layer 136 may be in contact with a third bump ball 86, and the twenty-fourth metal layer 142 may be in contact with a fourth bump ball 88. In one example, the twenty-third metal layer 138 may be a qubit layer. The twenty-fifth metal layer 144 may cover an entire upper surface of the eighth base layer 130. In one example, materials of the 22nd to 25th metal layers 136, 138, 142, and 144 may include superconducting materials and may be the same or different from each other. The material of at least some of the 22nd to 25th metal layers 136, 138, 142, and 144 may be the same as the material of the first metal layer 42.

The upper layer 500 may include an eighth through-hole 8h1 and a ninth through-hole 8h2. The eighth through-hole 8h1 may be located above the third bump ball 86, and the twenty-second metal layer 136 may exist between the eighth through-hole 8h1 and the third bump ball 86. The eighth through-hole 8h1 may be filled with an eighth conductive plug 132. An entire lower surface of the eighth conductive plug 132 may be covered with the 22nd metal layer 136 and may be in contact with the 22nd metal layer 136. An entire upper surface of the eighth conductive plug 132 may be covered with the twenty-fifth metal layer 144 and may be in contact with the twenty-fifth metal layer 144. In one example, a material of the eighth conductive plug 132 may be the same as the material of the first conductive plug 52 but is not limited thereto.

The ninth through-hole 8h2 may be located above the fourth bump ball 88, and the twenty-fourth metal layer 142 may exist between the ninth through-hole 8h2 and the fourth bump ball 88. The ninth through-hole 8h2 may be filled with a ninth conductive plug 146. An entire bottom of the ninth conductive plug 146 may be covered with the twenty-fourth metal layer 142 and may be in contact with the twenty-fourth metal layer 142. An entire upper surface of the ninth conductive plug 146 may be covered with the twenty-fifth metal layer 144 and may be in contact with the twenty-fifth metal layer 144. The material of the ninth conductive plug 146 may be the same as the material of the eighth conductive plug 132.

The twenty-third metal layer 138, which may be a qubit layer, may be disposed between the eighth through-hole 8h1 and the ninth through-hole 8h2 in the horizontal direction. The twenty-third metal layer 138 may be separated from the vertical rod layer 116 and may be located immediately above the vertical rod layer 116.

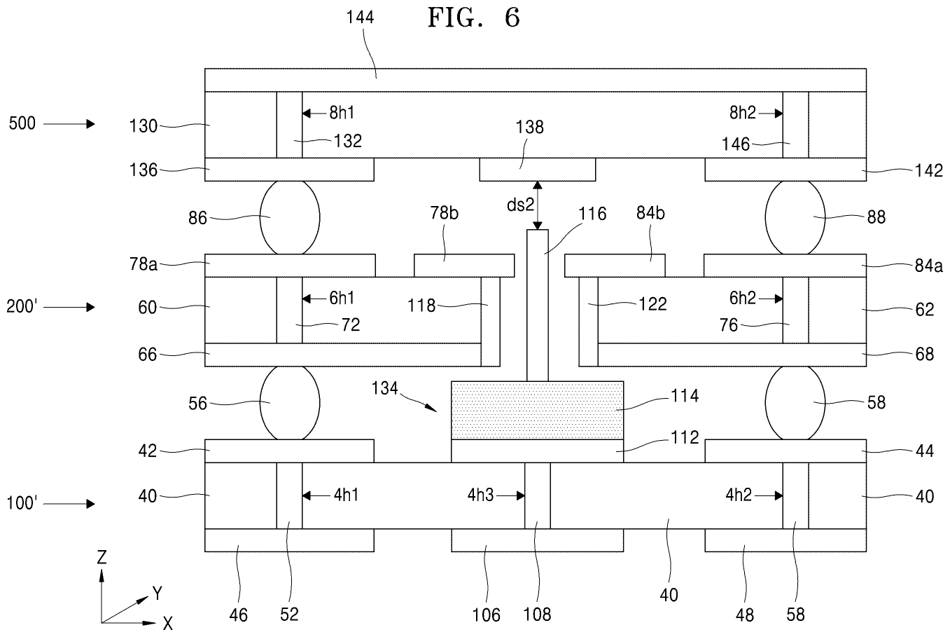

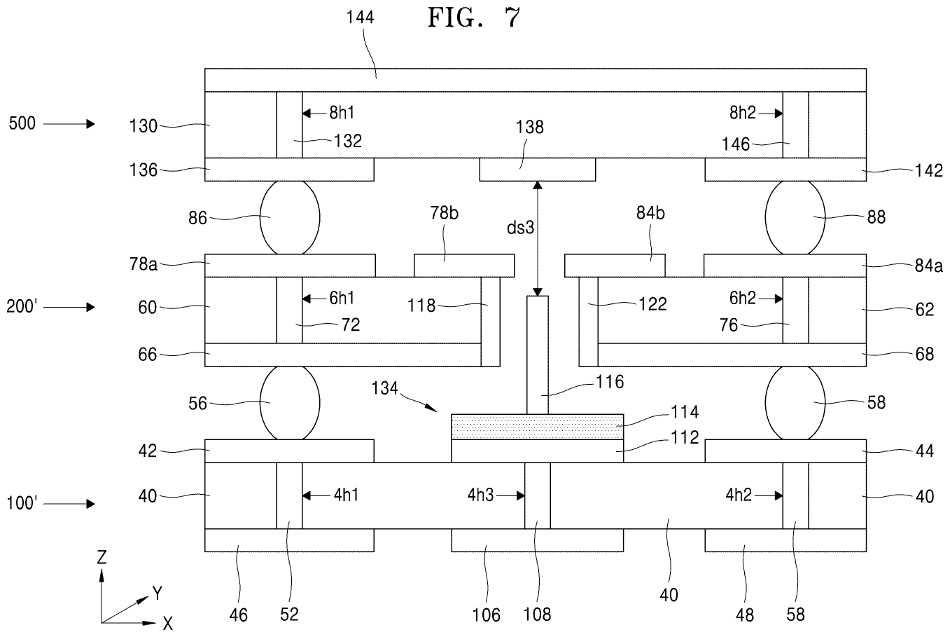

In an operation of the second quantum computer 2000, the seventh base layer 114 of the second coupling rate control element 134 may exhibit electrokinetic phenomena (e.g., expansion and contraction, etc.) according to a voltage applied to the seventh base layer 114. Accordingly, a height of the vertical rod layer 116 may be higher or lower than before the voltage is applied to the seventh base layer 114, as shown in FIGS. 6 and 7.

FIG. 6 shows a result of applying a voltage to the second coupling rate control element 134 so that the seventh base layer 114 expands in the vertical direction, according to one or more embodiments. As the seventh base layer 114 expands, the height of the vertical rod layer 116 becomes higher than before the voltage is applied. Accordingly, a distance ds2 between (i) the twenty-third metal layer 138 (which may be a qubit layer) and (ii) the vertical rod layer 116 becomes less than an initial distance ds1 before the voltage is applied. As a result, as the voltage is applied, a gap between the qubit layer 138 and the vertical rod layer 116 decreases and a capacitance between the qubit layer 138 and the vertical rod layer 116 increases, thus, the effective coupling rate between the qubit layer 138 and a transmission line of the middle layer 200′ may be increased.

FIG. 7 shows a case opposite to the case of FIG. 6, that is, a result of applying a voltage to the second coupling rate control element 134 so that the seventh base layer 114 contracts from the position of FIG. 5.

As the seventh base layer 114 contracts, the height of the vertical rod layer 116 becomes lower than before the voltage is applied. Accordingly, a distance ds3 between the twenty-third metal layer 138, which is a qubit layer, and the vertical load layer 116 becomes less than the initial distance ds1 in FIG. 5 before the voltage is applied. As a result, while the voltage is applied, the gap between the qubit layer 138 and the vertical rod layer 116 widens, and the capacitance between the qubit layer 138 and the vertical rod layer 116 decreases, thus, the effective coupling rate between the qubit layer 138 and a transmission line of the middle layer 200′ may be lowered.

If the qubit layer 138 is selected for operation, the coupling rate for the qubit layer 138 may be increased by increasing the height of the vertical rod layer 116 as shown in FIG. 6. In one example, if the qubit layer 138 is in an idle state and is not selected for operation, as shown in FIG. 7, the height of the vertical rod layer 116 is lowered to reduce the coupling rate with respect to the qubit layer 138, thereby preventing quality degradation and crosstalk of the qubit layer 138.

In the case of FIG. 6, the distance ds2 between the vertical rod layer 116 and the qubit layer 138 may be minimized within a range that does not deteriorate the quality of the qubit layer 138.

In one example, a copper layer may further be formed on lower surfaces of the metal layers 46, 48, and 106 provided on a lower surface of the lower layer 100′ of the second quantum computer 2000, and a copper layer may also be on lower surfaces of the metal layers 66 and 68 provided on a lower surface of the middle layer 200′.

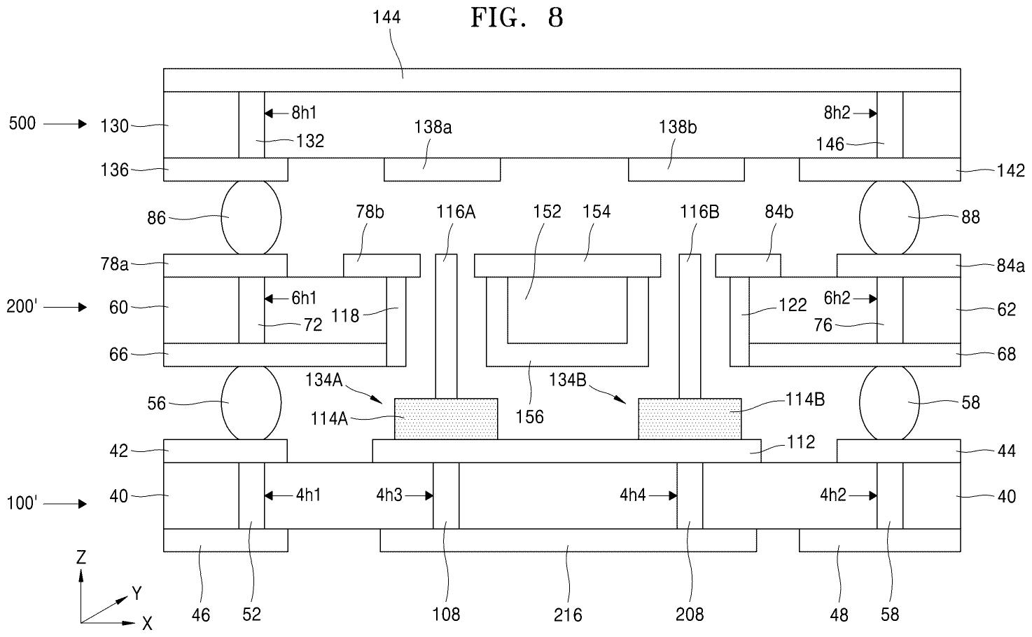

In one example, as illustrated in FIG. 8, on a lower surface of the upper layer 500 in FIG. 5, two metal layers 138a and 138b spaced apart from each other (a first qubit layer 138a and a second qubit layer 138b) may be between the eighth through-hole 8h1 and the ninth through-hole 8h2. In addition, on an upper surface of the lower layer 100′ between the first and second through-holes 4h1 and 4h2, a third coupling rate control element 134A corresponding to the first qubit layer 138a and a fourth coupling rate control element 134B corresponding to the second qubit layer 138b may be disposed. The layer configuration (structure) of each of the third and fourth coupling rate control elements 134A and 134B may be the same as the second coupling rate control element 134 of FIG. 5. Therefore, the operation process of the third and fourth coupling rate control elements 134A and 134B may be the same as the operation process of the second coupling rate control element 134 of FIG. 5. Accordingly, the coupling rate for the first qubit layer 138a and the second qubit layer 138b may be adjusted by controlling the application direction and/or size of a voltage applied to the third and fourth coupling rate control elements 134A and 134B. As an example, the voltage may be applied under a condition that a height of the vertical rod layer of the coupling rate control element corresponding to one of the first and second qubit layers 138a and 138b is increased and the height of the vertical rod layer of the coupling rate control element corresponding to the remaining qubit layer is reduced. In one example, when both the first and second qubit layers 138a and 138b are qubits selected for operation, the voltage may be applied under a condition that the height of the vertical rod layers 116A and 116B of the third and fourth coupling rate control elements 134A and 134B are increased, thus increasing the coupling rate of the first and second qubit layers 138a and 138b but within a range that does not deteriorate the quality of the qubit layer.

Conversely, when both the first and second qubit layers 138a and 138b are in an idle state during the operation process with respect to another qubit layer, the voltage may be applied under the condition that the height of the vertical rod layers 116A and 116B of the third and fourth coupling rate control elements 134A and 134B are reduced to reduce the coupling rate of the first and second qubit layers 138a and 138b lower than a set value. In this way, the degree that the first and second qubit layers 138a and 138b are affected during an operation process may be reduced. That is, there may be little or no effect on the first and second qubit layers 138a and 138b during the operation process. Accordingly, the quality degradation and/or crosstalk of the first and second qubit layers 138a and 138b may be reduced or prevented.

A ninth base layer 114A of the third coupling rate control element 134A and a tenth base layer 114B of the fourth coupling rate control element 134B may be formed on a common metal layer 112. That is, the two base layers 114A and 114B may be formed on one metal layer 112. A material of the metal layer 112 may be the same as the material of the first metal layer 42.

An eleventh base layer 152 may exist between the second and third base layers 60 and 62 in the middle layer 200′. The eleventh base layer 152 may be spaced apart from the second and third base layers 60 and 62. A material of the eleventh base layer 152 may be the same as the material of the second base layer 60 or the third base layer 62 but is not limited thereto. An upper surface of the eleventh base layer 152 may be covered with a twenty-sixth metal layer 154, and may be in direct contact with the twenty-sixth metal layer 154. Side and lower surfaces of the eleventh base layer 152 may be covered with a twenty-seventh metal layer 156, and may be in direct contact with the twenty-seventh metal layer 156. The third coupling rate control element 134A may be between the second base layer 60 and the eleventh base layer 152. The vertical rod layer 116A may be located between the twentieth metal layer 118 and the twenty-seventh metal layer 156. An upper end of the vertical rod layer 116A may be located between the sixth metal layer 78b and the twenty-sixth metal layer 154. The fourth coupling rate control element 134B may be between the third base layer 62 and the eleventh base layer 152. The vertical rod layer 116B may be located between the twenty-first metal layer 122 and the twenty-seventh metal layer 156. An upper end of the vertical rod layer 116B may be located between the ninth metal layer 84b and the twenty-sixth metal layer 154.

A tenth through-hole 4h4 may be formed between the seventh through-hole 4h3 and the second through-hole 4h2 in the first base layer 40 of the lower layer 100′. The tenth through-hole 4h4 may be separated from the second and seventh through-holes 4h2 and 4h3. The tenth through-hole 4h4 may be filled with a tenth conductive plug 208, and a material of the tenth conductive plug 208 may be the same as the material of the first conductive plug 52 but is not limited thereto. The seventh through-hole 4h3 may be located at a position corresponding to the third coupling rate control element 134A, and the tenth through-hole 4h4 may be at a position corresponding to the fourth coupling rate control element 134B. In one example, the seventh through-hole 4h3 may be formed below the ninth base layer 114A of the third coupling rate control element 134A, and the tenth through-hole 4h4 may be formed below the tenth base layer 114B of the fourth coupling rate control element 134B.

A twenty-eighth metal layer 216 corresponding to the nineteenth metal layer 112 may be on a lower surface of the first base layer 40 of the lower layer 100′. The twenty-eighth metal layer 216 may be spaced apart from the third and fourth metal layers 46 and 48. A material of the twenty-eighth metal layer 216 may be the same as or different from the material of the third metal layer 46 or the fourth metal layer 48. A thickness of the twenty-eighth metal layer 216 may be substantially the same as or different from the thickness of the third and/or fourth metal layers 46 and 48. The twenty-eighth metal layer 216 may completely cover lower entrances of the seventh through-hole 4h3 and the tenth through-hole 4h4, and thus, may contact an entire lower surface of the seventh conductive plug 108 that fills the seventh through-hole 4h3 and an entire lower surface of the eighth conductive plug 208 that fills the tenth through-hole 4h4.

In one example, power (e.g., direct current power) may be transmitted to the seventh base layer 114 of FIG. 5 or the ninth base layer 114A and tenth base layer 114B of FIG. 8 through a specific pin.

In one example, an element (e.g., lever or torsion spring, etc.) for moving the seventh base layer 114 of FIG. 5 or the ninth base layer 114A and the tenth base layer 114B of FIG. 8 in the vertical direction may further be included.

In one example, the first and second quantum computers 1000 and 2000 described above may include quantum memory cells as represented by the equivalent circuit of FIG. 4, and the quantum memory cells may be connected to a superconductor transmission line. In one example, each quantum memory cell and transmission line may be connected by a Josephson junction.

The disclosed superconductor-based quantum computer includes a coupling rate control element equipped with a metal layer that forms capacitive coupling with a transmission line and qubits. In the operation of the quantum computer, the degree of capacitive coupling of the metal layer with respect to a transmission line and/or a qubit may be adjusted by controlling a voltage applied to the coupling rate control element. Therefore, among the qubits included in the quantum computer, a voltage may be applied in a direction to strengthen the capacitive coupling to the coupling rate control element corresponding to the qubit that is a target of the operation (selected qubit participating in the operation), and a voltage may be applied in a direction to weaken the capacitive coupling to the coupling rate control element corresponding to an unselected qubit that does not participate in the operation among the qubits. Strengthening the capacitive coupling may be maximized in a range that does not deteriorate the quality of the selected qubit. Accordingly, the speed of operation (e.g., state control or measurement) may be increased while preventing quality degradation for the selected qubits, and crosstalk and quality degradation for the unselected qubits may be prevented. Due to these advantages, the number of qubits constituting a logical qubit may be reduced compared to the prior art.

While the present inventive concept has been particularly shown and described with reference to embodiments thereof, it should not be construed as being limited to the embodiments set forth herein rather than limiting the scope of the disclosure. Therefore, the scope of the present inventive concept should not be defined by the described embodiments but should be defined by the technical spirit of the appended claims set forth herein.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A superconductor-based quantum computer comprising:
a lower layer including a multi-chip module;
a middle layer provided above the lower layer and connected with the lower layer;
an upper layer provided above the middle layer and connected with the middle layer, wherein the upper layer comprises a qubit layer;
the middle layer comprising:
a superconductor transmission line through which electromagnetic waves for controlling the qubit layer are transmitted; and
a first coupling rate control element provided at a position corresponding to the qubit layer below the upper layer, spaced apart from the transmission line and the qubit layer, and provided to adjust a coupling rate between the transmission line and the qubit layer;
the first coupling rate control element comprising:
a movable material layer, a boundary of which is physically movable depending on a voltage applied thereto; and
a metal layer provided on a surface of the movable material layer, the metal layer facing the qubit layer and forming a capacitive coupling with the qubit layer and the transmission line.

2. The superconductor-based quantum computer of claim 1, wherein the first coupling rate control element is included in the middle layer.

3. The superconductor-based quantum computer of claim 2, wherein the first coupling rate control element is provided by a floating state of the movable material layer in the middle layer.

4. The superconductor-based quantum computer of claim 3, wherein
the qubit layer comprises a first qubit layer and a second qubit layer spaced apart from each other,
wherein the metal layer comprises:
a first metal layer provided at a position corresponding to the first qubit layer; and
a second metal layer provided at a position corresponding to the second qubit layer.

5. The superconductor-based quantum computer of claim 1, wherein
the first coupling rate control element is provided on the lower layer, has a layer structure facing the qubit layer, and is spaced apart from the middle layer.

6. The superconductor-based quantum computer of claim 5, wherein the metal layer comprises a vertical rod protruding from the movable material layer toward the qubit layer.

7. The superconductor-based quantum computer of claim 5, wherein
the qubit layer comprises a first qubit layer and a second qubit layer spaced apart from each other,
the first coupling rate control element is provided to correspond to the first qubit layer, and
a second coupling rate control element is provided to correspond to the second qubit layer, and
the second coupling rate control element has a same layer structure as the layer structure of the first coupling rate control element.

8. The superconductor-based quantum computer of claim 6, wherein the movable material layer comprises a piezoelectric material.

9. The superconductor-based quantum computer of claim 1, wherein
the movable material layer comprises a material that performs an electrokinetic movement in response to an electrostatic force, electromagnetic force, piezoelectric force, and/or thermo-electric force applied thereto.

10. The superconductor-based quantum computer of claim 1, wherein
the middle layer comprises two base layers spaced apart from each other, the transmission line is provided on surfaces of the two base layers, and the first coupling rate control element is provided between the two base layers.

11. The superconductor-based quantum computer of claim 1, wherein the lower layer, the middle layer, and the upper layer are vertically connected with each other via bump balls.

12. The superconductor-based quantum computer of claim 1, wherein the movable material layer and the metal layer include a same material.

13. An operating method of a superconductor-based quantum computer, the operating method comprising:
with respect to a coupling rate control element that is at a given distance from a transmission line and a qubit layer before an operating voltage is applied to the coupling rate control element, adjusting a gap between the transmission line and/or qubit layer and the coupling rate control element by applying a first operating voltage to the coupling rate control element;
the coupling rate control element comprising:
a movable material layer, a boundary of which is movable depending on an applied voltage; and
a metal layer on a surface of the movable material layer that faces the qubit layer and the metal layer forming a capacitive coupling with the qubit layer and the transmission line.

14. The operating method of claim 13, wherein the adjusting of the gap between the transmission line and/or qubit layer and the coupling rate control element comprises:
moving the movable material layer closer to the transmission line and/or the qubit layer to strengthen the capacitive coupling.

15. The operating method of claim of claim 13, wherein
the adjusting of the gap comprises:
moving the movable material layer away from the transmission line and/or the qubit layer to weaken the capacitive coupling.

16. The operating method of claim of claim 13, wherein
the adjusting of the gap comprises:
expanding the movable material layer toward the transmission line and/or the qubit layer to strengthen the capacitive coupling.

17. The operating method of claim of claim 13, wherein
the adjusting of the gap comprises:
contracting the movable material layer in a direction opposite to the transmission line and/or the qubit layer to weaken the capacitive coupling.

18. The operating method of claim of claim 13, wherein
the qubit layer includes multiple qubit layers spaced apart from each other, and
the coupling rate control element comprises coupling rate control elements respectively corresponding to the qubit layers,
wherein the coupling rate control elements comprise:
a first coupling rate control element corresponding to a first qubit layer selected for operation from among the plurality of qubit layers; and
a second coupling rate control element corresponding to a second qubit layer that is in an idle state and does not participate in the operation from among the plurality of qubit layers,
wherein a voltage for increasing the coupling rate between the first qubit layer and the transmission line is applied to the first coupling rate control element, and
a voltage to weaken the coupling rate between the second qubit layer and the transmission line is applied to the second coupling rate control element.

19. The operating method of claim of claim 13, wherein the metal layer comprises a vertical rod layer protruding from the movable material layer toward the qubit layer.

20. The operating method of claim of claim 13, wherein
the movable material layer comprises a material that performs an electrokinetic movement in response to an electrostatic force, electromagnetic force, piezoelectric force, and/or thermal-electric force applied thereto.
